(19) United States
(12) Patent Application Publication
(10) Pub. No.: US 2026/0136595 A1
(43) Pub. Date: May 14, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Man-Nung SU, Taipei City (TW); Po-Chin CHANG, Taichung City (TW); Chia-Hung CHU, Taipei City (TW); Meng-Hsi CHUANG, Hsinchu City (TW); Sung-Li WANG, Zhubei Township (TW); Pinyen LIN, Rochester, NY (US)

(21) Appl. No.: 18/944,692

(22) Filed: Nov. 12, 2024

(51) Int. Cl. H01L 29/417; H01L 21/02; H01L 21/768; H01L 29/06; H01L 29/66; H01L 29/775; H01L 29/78; H01L 29/786

(52) U.S. Cl. CPC H10D 30/6729; H10D 30/014; H10D 30/43; H10D 30/6219; H10D 30/6757; H10D 62/121; H10P 14/6682; H10W 20/048; H10W 20/075; H10W 20/097; H10D 30/024; H10D 30/62

(57) ABSTRACT

Semiconductor structures and methods for manufacturing the same are provided. The semiconductor structure includes a gate structure formed over a substrate, and a source/drain (S/D) structure formed adjacent to the gate structure. The semiconductor structure includes an S/D conductive plug over the S/D structure and in a dielectric layer, and a protruding conductive structure on the S/D conductive plug. The protruding conductive structure extends above a top surface of the dielectric layer. The semiconductor structure includes a conductive layer formed on the protruding conductive structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1F illustrate perspective views of intermediate stages of manufacturing a semiconductor structure in accordance with some embodiments.

FIGS. 2A to 2Q illustrate cross-sectional representations of various stages of manufacturing the semiconductor structure shown along line A-A′ in FIG. 1F, in accordance with some embodiments.

FIG. 3 illustrates a top view of the semiconductor structure, in accordance with some embodiments.

FIG. 4 illustrates a bottom view of the semiconductor structure, in accordance with some embodiments.

FIGS. 5A-5H illustrates a cross-sectional views of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a fin structure over a substrate. A gate structure formed over the fin structure and an S/D structure adjacent to the gate structure. An S/D contact structure is formed on the S/D structure, and an S/D conductive plug is formed on the S/D contact structure. A gate conductive plug is formed on the gate structure. The protruding conductive structures are formed on the S/D conductive plug and the gate conductive plug. The protruding conductive structures extends upwardly above the top surface of the dielectric layer. The protruding conductive structures can be selectively formed on the conductive materials, not on the dielectric materials. The contact area between the protruding conductive structures and overlying layers is increased, and therefore the contact resistance is decreased. Therefore, the performance of the semiconductor structure is improved. The Source/drain (S/D) structure or S/D region(s) may refer to a source or a drain, individually or collectively dependent upon the context.

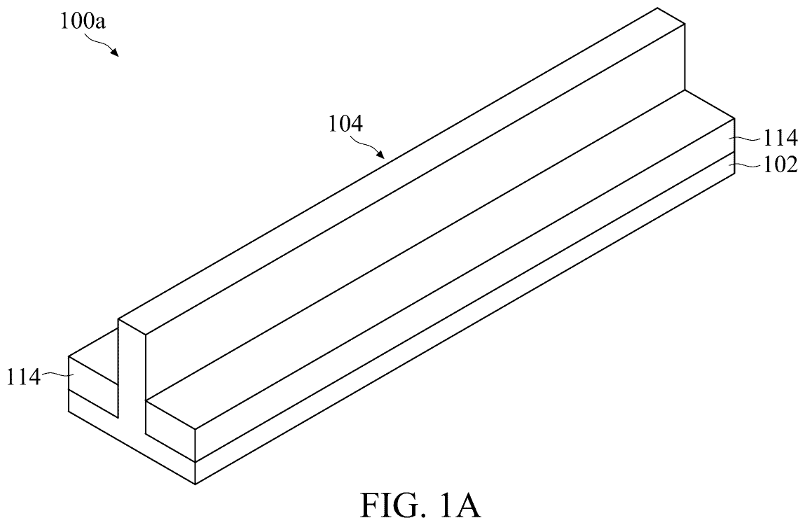

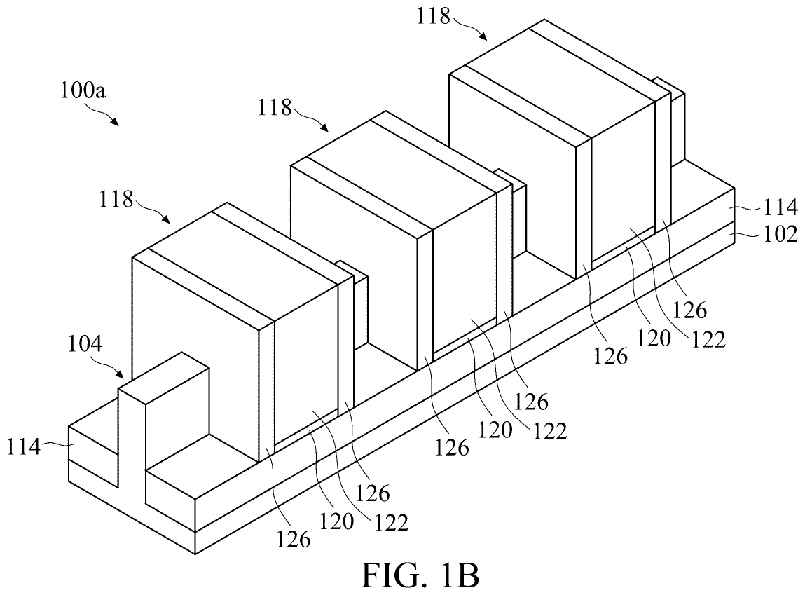

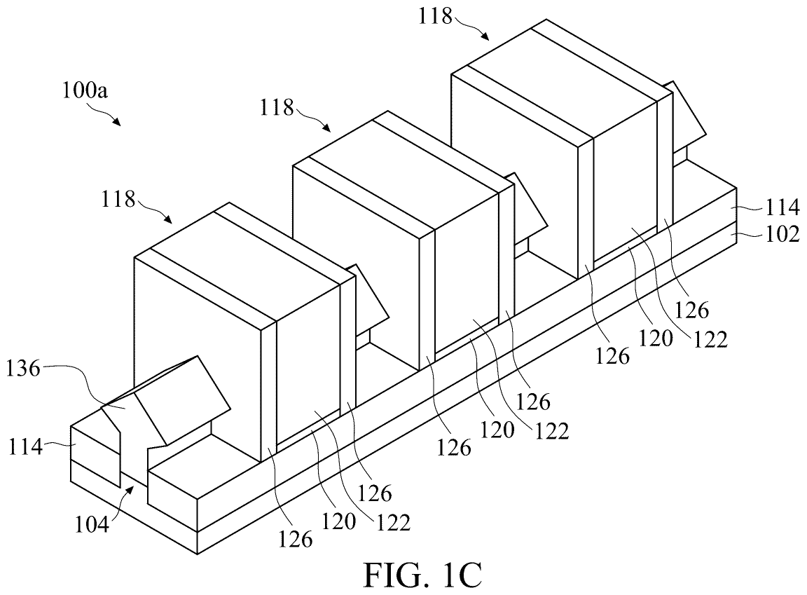

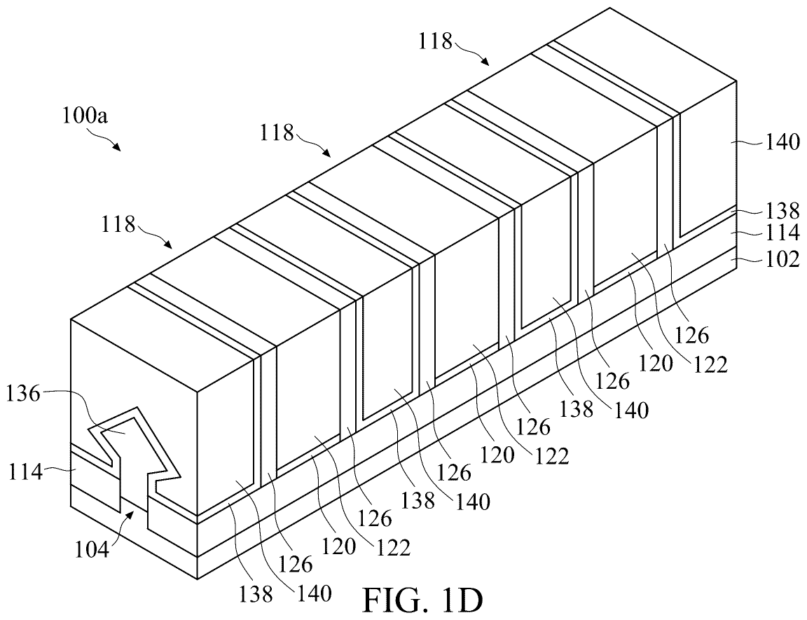

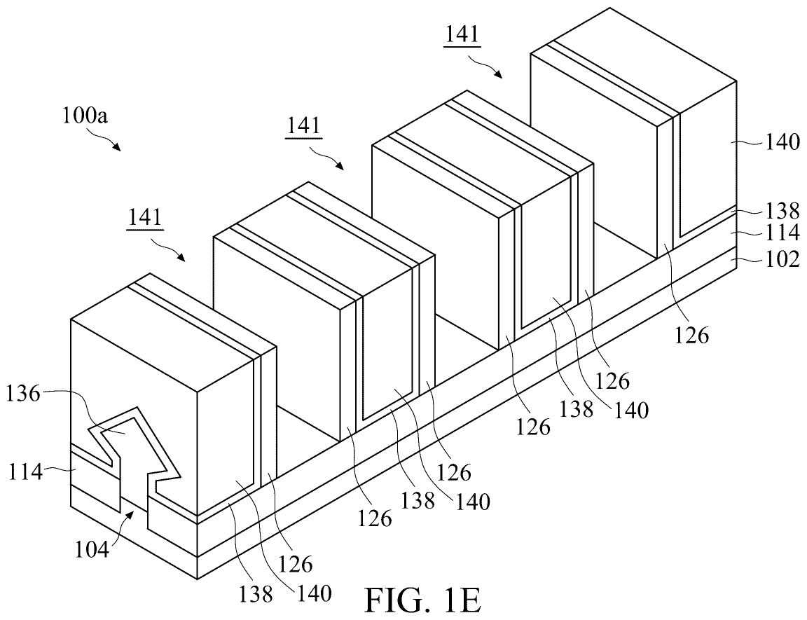

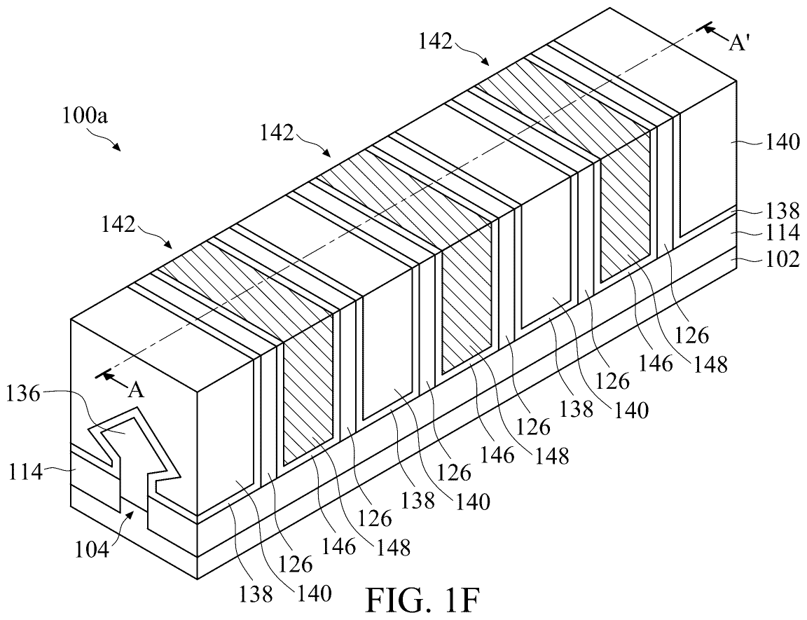

Embodiments for forming a fin field effect transistor (FinFET) device structure are provided. FIGS. 1A-1F show perspective representations of various stages of forming a semiconductor structure 100a, in accordance with some embodiments of the disclosure.

Referring to FIG. 1A, a substrate 102 is provided. The substrate 102 may be made of silicon or other semiconductor materials. Alternatively or additionally, the substrate 102 may include other elementary semiconductor materials such as germanium. In some embodiments, the substrate 102 is made of a compound semiconductor such as silicon carbide, gallium arsenic, indium arsenide, or indium phosphide. In some embodiments, the substrate 102 is made of an alloy semiconductor such as silicon germanium, silicon germanium carbide, gallium arsenic phosphide, or gallium indium phosphide. In some embodiments, the substrate 102 includes an epitaxial layer. For example, the substrate 102 has an epitaxial layer overlying a bulk semiconductor.

Afterwards, a fin structure 104 is formed on the substrate 102. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

In some embodiments, the substrate 102 is etched using a dry etching process. The dry etching process includes using a fluorine-based etchant gas, such as SF₆, CₓF_{y}, NF₃ or a combination thereof. The etching process may be a time-controlled process, and continue until the fin structure 104 reaches a predetermined height. In some other embodiments, the fin structure 104 has a width that gradually increases from the top portion to the lower portion.

Next, after the fin structure 104 is formed, an insulating layer is formed to cover the fin structure 104 over the substrate 102. In some embodiments, the insulating layer is made of silicon oxide, silicon nitride, silicon oxynitride, fluoride-doped silicate glass (FSG), low-k dielectric material or another applicable material. The insulating layer may be deposited by a chemical vapor deposition (CVD) process, a spin-on-glass process, or another applicable process.

Afterwards, the insulating layer is thinned by a polishing process, and then is removed by an etching process, in accordance with some embodiments. As a result, an isolation structure 114 is obtained. The isolation structure 114 may be a shallow trench isolation (STI) structure surrounding the fin structure 104. A lower portion of the fin structure 104 is surrounded by the isolation structure 114, and an upper portion of the fin structure 104 protrudes from the isolation structure 114. In other words, a bottom portion of the fin structure 104 is embedded in the isolation structure 114. The isolation structure 114 prevents electrical interference and crosstalk.

Afterwards, as shown in FIG. 1B, a dummy gate structure 118 is formed across the fin structure 104 and extends over the isolation structure 114, in accordance with some embodiments. In some embodiments, the dummy gate structure 118 includes a dummy gate dielectric layer 120 and a dummy gate electrode layer 122 formed over the dummy gate dielectric layer 120. In some embodiments, the dummy gate dielectric layer 120 includes silicon oxide, and the dummy gate electrode layer 122 includes polysilicon. After the dummy gate structure 118 is formed, the gate spacer layers 126 are formed on opposite sidewall surfaces of the dummy gate structure 118. The gate spacer layers 126 may be a single layer or multiple layers.

In order to improve the speed of the semiconductor structure 100a, the gate spacer layers 126 are made of low-k dielectric materials. In some embodiments, the low-k dielectric materials has a dielectric constant (k value) is less than 4. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

In some other embodiments, the gate spacer layers 126 are made of an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), or porous silicon oxide (SiO₂). In some embodiments, the gate spacer layers 126 are formed by chemical vapor deposition (CVD), physical vapor deposition (PVD), atomic layer deposition (ALD), or other applicable processes.

Afterwards, as shown in FIG. 1C, source/drain (S/D) structures 136 are formed over the fin structure 104, in accordance with some embodiments. In some embodiments, portions of the fin structure 104 adjacent to the dummy gate structure 118 are recessed to form recesses at two sides of the fin structure 104, and a strained material is grown in the recesses by an epitaxial (epi) process to form the S/D structures 136. In addition, the lattice constant of the strained material may be different from the lattice constant of the substrate 102. In some embodiments, the S/D structures 136 include Ge, SiGe, InAs, InGaAs, InSb, GaAs, GaSb, InAlP, InP, or the like.

In some embodiments, the source/drain (S/D) structures 136 are in-situ doped during the epitaxial growth process. For example, the source/drain (S/D) structure 136 may be the epitaxially grown SiGe doped with boron (B). For example, the source/drain (S/D) structure 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the source/drain (S/D) structure 136 are doped in one or more implantation processes after the epitaxial growth process.

Afterwards, as shown in FIG. 1D, a contact etch stop layer (CESL) 138 is formed over the substrate 102, and an inter-layer dielectric (ILD) layer 140 is formed over the CESL 138, in accordance with some embodiments. In some other embodiments, the CESL 138 is made of silicon nitride, silicon oxynitride, and/or other applicable materials. The CESL 138 may be formed by plasma enhanced CVD, low-pressure CVD, ALD, or other applicable processes.

The ILD layer 140 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 140 may be formed by chemical vapor deposition (CVD), physical vapor deposition (PVD), atomic layer deposition (ALD), spin-on coating, or another applicable process.

Afterwards, a polishing process is performed on the ILD layer 140 until the top surface of the dummy gate structure 118 is exposed. In some embodiments, the ILD layer 140 is planarized by a chemical mechanical polishing (CMP) process.

Afterwards, as shown in FIG. 1E, the dummy gate structure 120 is removed to form a trench 141 in the ILD layer 140, in accordance with some embodiments. The dummy gate dielectric layer 120 and the dummy gate electrode layer 122 are removed by an etching process, such as a dry etching process or a wet etching process.

Next, as shown in FIG. 1F, a gate structure 142 is formed in the trench 141, in accordance with some embodiments. The gate structure 142 includes a gate dielectric layer 146 and a gate electrode layer 148.

The gate dielectric layer 146 may be a single layer or multiple layers. The gate dielectric layer 146 is made of silicon oxide (SiOx), silicon nitride (SixNy), silicon oxynitride (SiON), dielectric material(s) with high dielectric constant (high-k), or a combination thereof. The high dielectric constant (high-k) material may be hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. In some embodiments, the gate dielectric layer 146 is deposited by a plasma enhanced chemical vapor deposition (PECVD) process or by a spin coating process.

The gate electrode layer 148 is made of conductive material, such as aluminum (Al), copper (Cu), tungsten (W), titanium (Ti), tantalum (Ta), or other applicable materials.

In some embodiments, the gate structure 142 further includes a work function layer. The work function layer is made of metal material, and the metal material may include N-work-function metal or P-work-function metal. The N-work-function metal includes tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal includes titanium nitride (TiN), tungsten nitride (WN), tantalum nitride (TaN), ruthenium (Ru) or a combination thereof.

The gate electrode layer 148 is formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

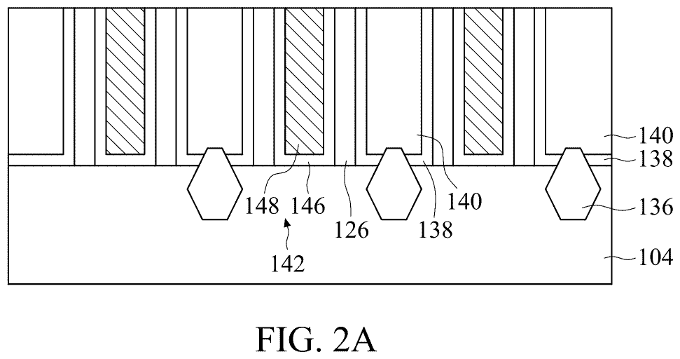

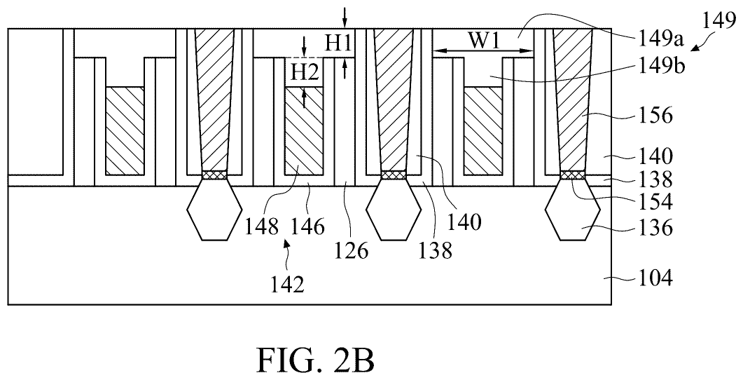

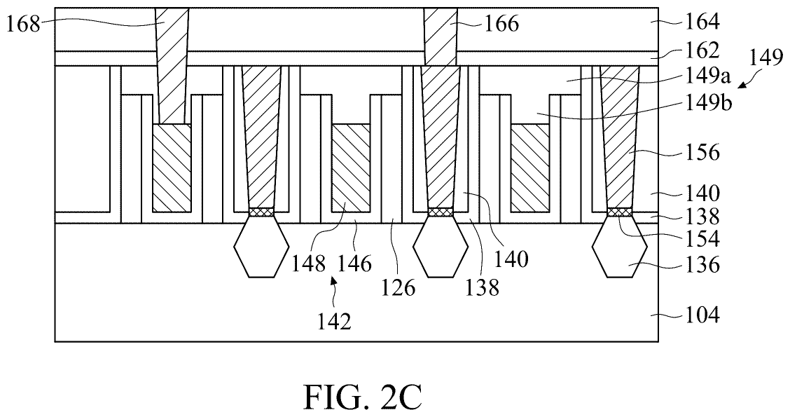

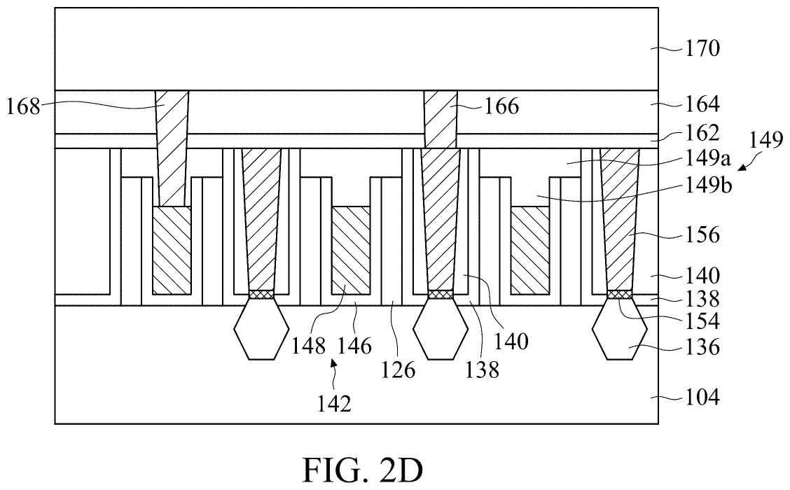

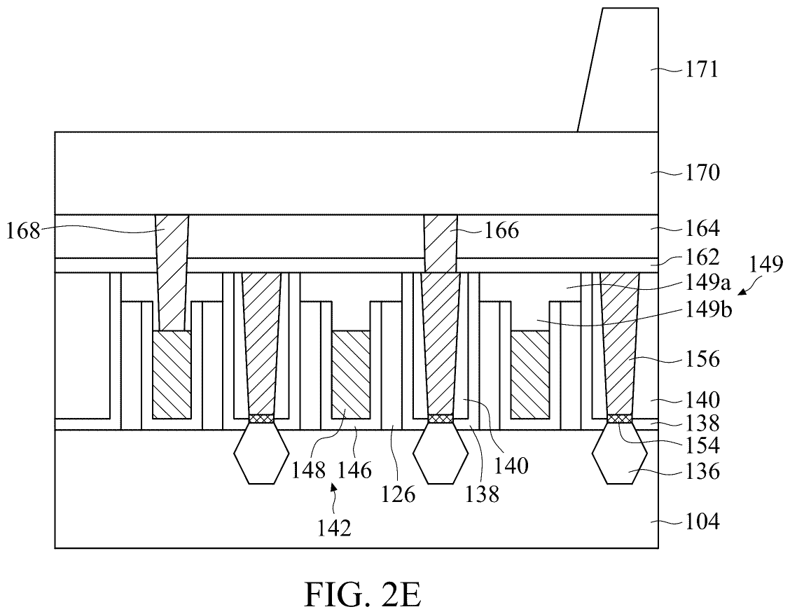

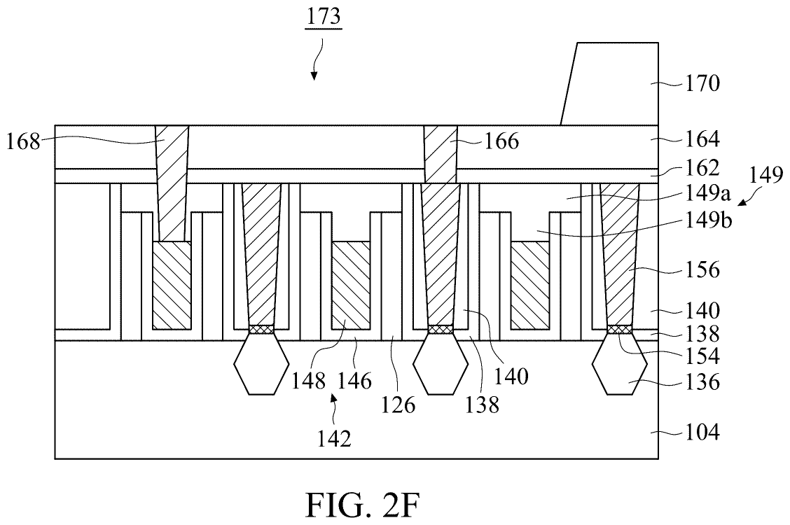

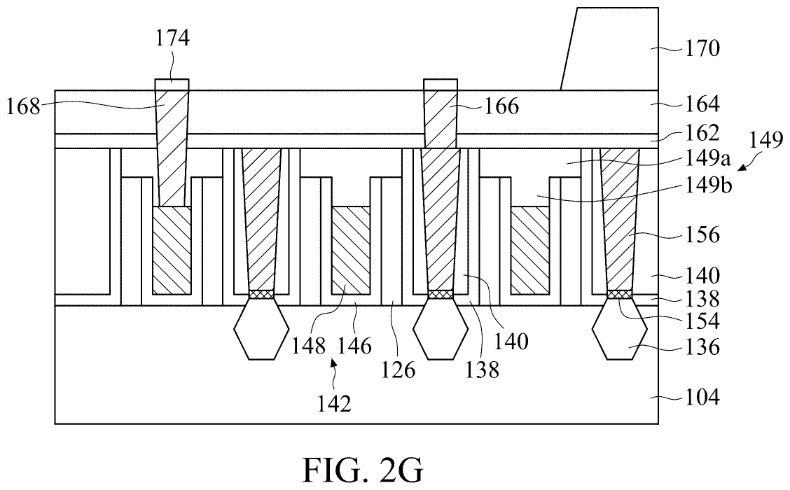

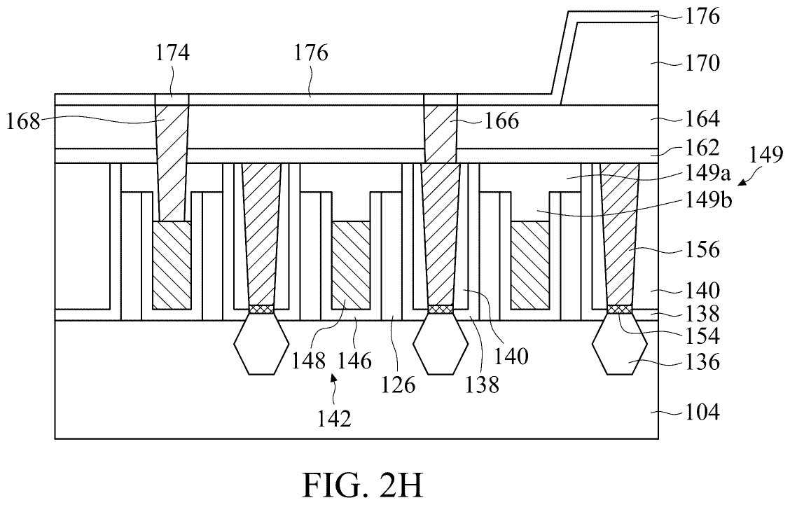

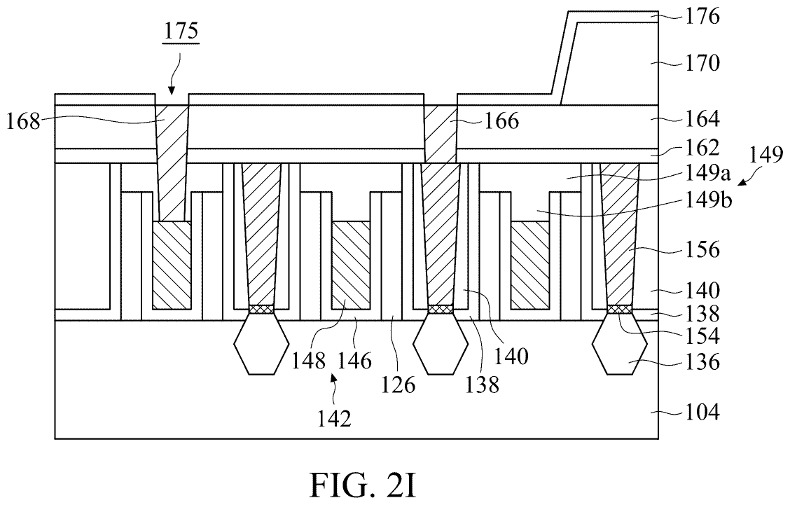

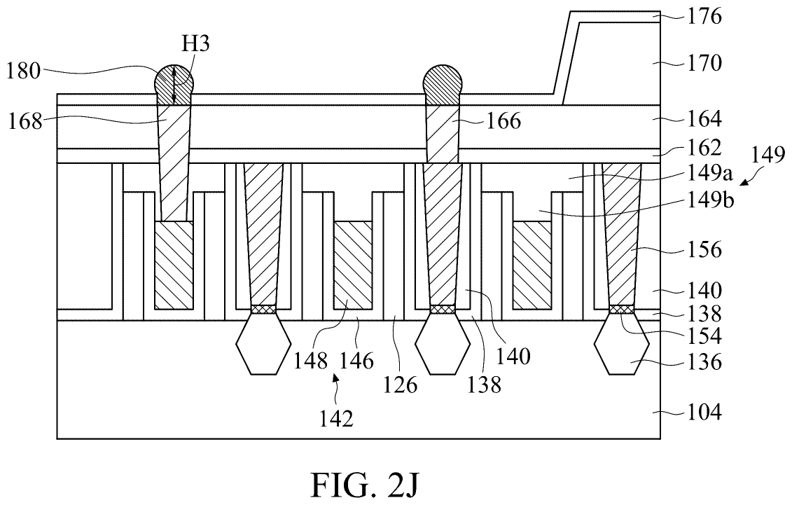

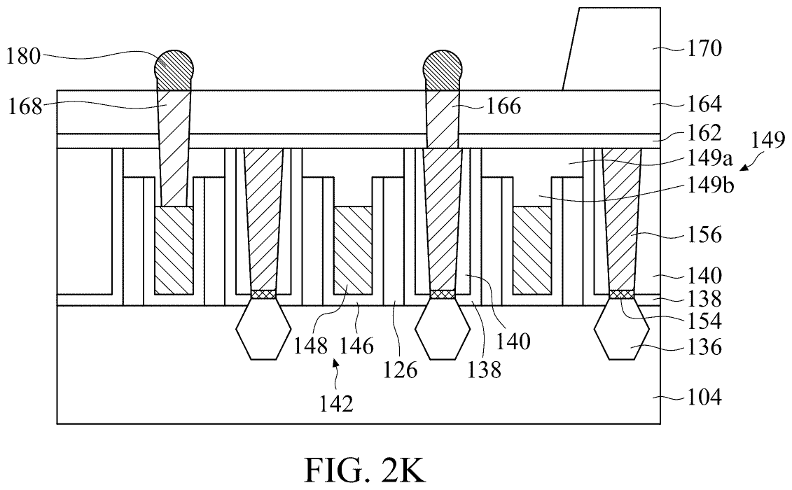

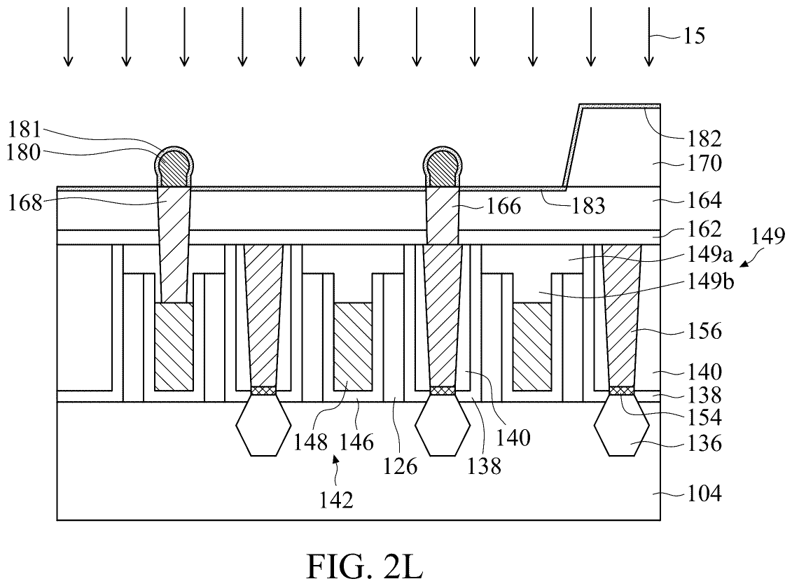

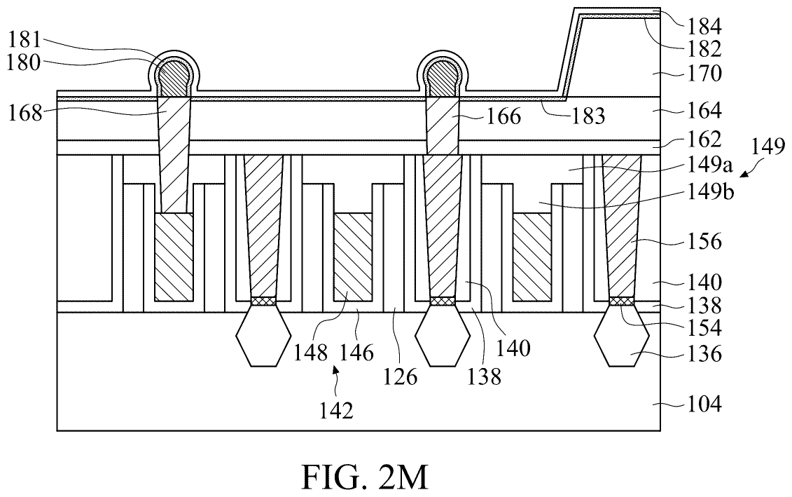

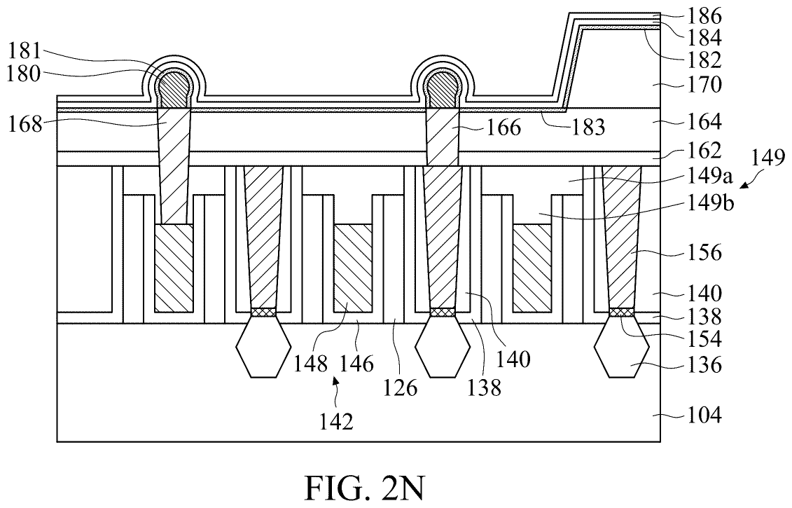

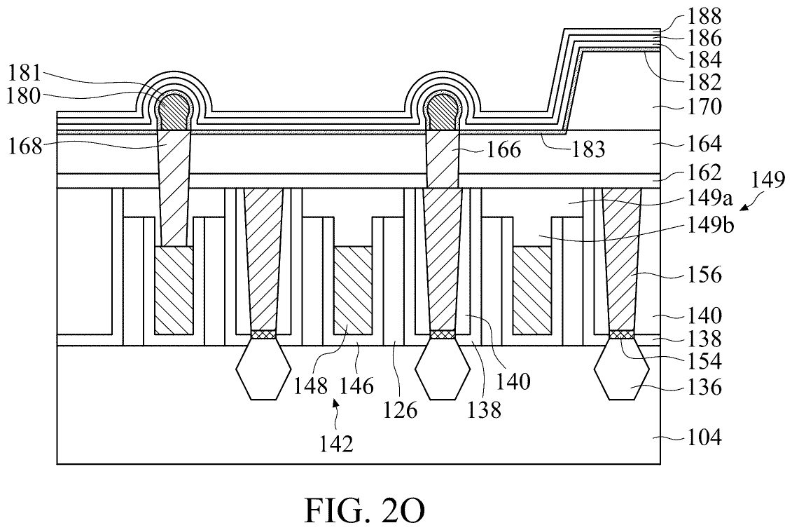

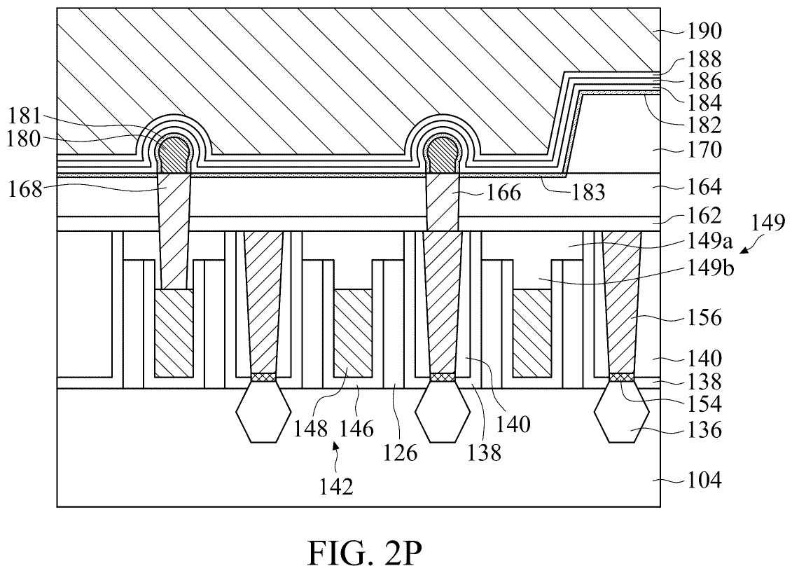

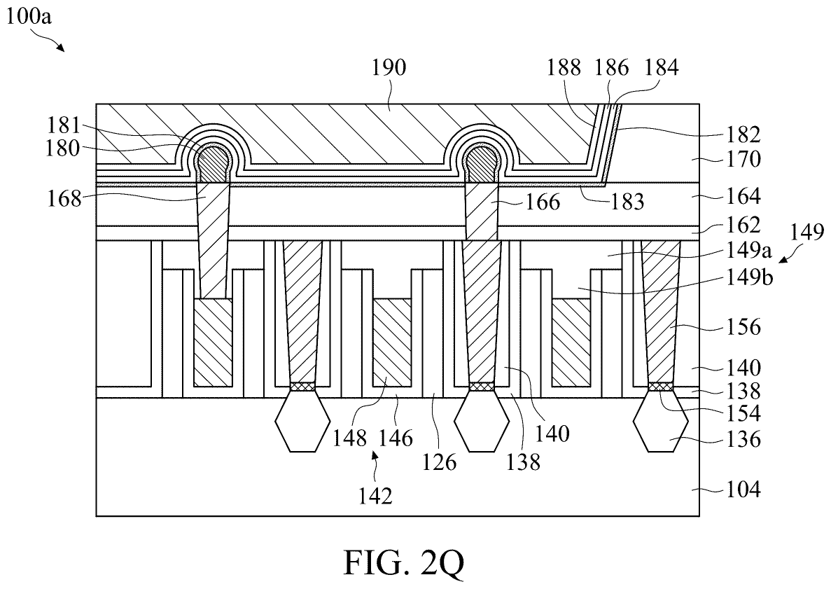

FIGS. 2A-2Q illustrate cross-sectional representations of various stages of manufacturing the semiconductor structure 100a shown along line A-A′ in FIG. 1F, in accordance with some embodiments.

More specifically, FIG. 2A illustrates the cross-sectional representation shown along line A-A′ in FIG. 1F, in accordance with some embodiments.

Next, as shown in FIG. 2B, a top portion of the gate structure 142 is removed, and a top portion of the gate spacer layer 126 is removed to form a trench (not shown), and then a gate mask layer 149 is formed in the trench, in accordance with some embodiments.

In some embodiments, the gate mask layer 149 has a T-shaped structure. In some other embodiments, the gate mask layer 149 has a rectangular shape. In some embodiments, the gate mask layer 149 is made of LaO, AlO, YO, TaCN, ZrSi, SiOCN, SiOC, SiCN, LaO, ZrN, ZrAlO, TiO, TaO, ZrO, HfO, SiN, HfSi, AlON, SiO, SiC, ZnO or a combination thereof. In some embodiments, the gate mask layer 149 is formed by chemical vapor deposition (CVD), physical vapor deposition (PVD), atomic layer deposition (ALD), or other applicable processes.

The gate mask layer 149 has a top portion 149a and a bottom portion 149b, the top portion 149a is formed on the top surface of the gate spacer layer 126 and the top surface of the gate dielectric layer 146. The bottom portion 149b of the gate mask layer 149 is formed on the top surface of the gate electrode layer 148. The top portion 149a of the gate mask layer 149 has a first height H1. In some embodiments, the first height H1 is in a range from about 1 nm to about 30 nm. The bottom portion 149b of the gate mask layer 149 has a second height H2. In some embodiments, the second height H2 is in a range from about 1 nm to about 50 nm. The top portion 149a of the gate mask layer 149 has a first width W1. In some embodiments, the first width W1 is in a range from about 2 nm to about 50 nm.

Afterwards, a portion of the ILD layer 140 and a portion of the CESL 138 are removed to form a contact opening (not shown), in accordance with some embodiments. Subsequently, a silicide layer 154 and an S/D contact structure 156 is formed on the S/D structure 136. The top surface of the gate mask layer 149 is substantially coplanar with the top surface of the S/D contact structure 156. The S/D contact structure 156 is electrically connected to the S/D structure 136 by the silicide 154.

The silicide layers 154 may be formed by forming a metal layer over the top surfaces of the S/D structure 136 and annealing the metal layer so the metal layer reacts with the S/D structure 136 to form the silicide layers 154. The unreacted metal layer may be removed after the silicide layers 154 are formed.

The S/D contact structure 156 may include a barrier layer and a conductive layer. In some other embodiments, the S/D contact structure 156 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition (PVD), atomic layer deposition (ALD), or other applicable processes.

Afterwards, as shown in FIG. 2C, an etch stop layer 162 is formed over the gate structure 142, and a dielectric layer 164 is formed over the etch stop layer 162, in accordance with some embodiments.

In some embodiments, the etch stop layer 162 is made of a dielectric materials, such as silicon nitride, silicon oxide, silicon oxynitride, another suitable dielectric material, or a combination thereof. The dielectric material for the etch stop layers 162 may be conformally deposited over the semiconductor structure by performing chemical vapor deposition (CVD), ALD, other application methods, or a combination thereof. In some embodiments, the etch stop layer 162 has a thickness in a range from about 2 nm to about 20 nm.

The dielectric layer 164 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 164 may be formed by chemical vapor deposition (CVD), physical vapor deposition (PVD), atomic layer deposition (ALD), or other applicable processes. In some embodiments, the dielectric layer 164 has a thickness in a range from about 2 nm to about 20 nm.

Next, an S/D conductive plug 166 is formed over the S/D contact structure 156, and a gate conductive plug 168 is formed over the gate structure 142. The S/D conductive plug 166 is electrically connected to the S/D contact structure 156. The S/D conductive plug 166 is electrically connected to the S/D structure 136 by the S/D contact structure 156. The gate conductive plug 168 is electrically connected to the gate electrode layer 148 of the gate structure 142. In addition, the gate conductive plug 168 passes through the gate mask layer 149. The top surface of the S/D conductive plug 166 is substantially coplanar with the top surface of the gate conductive plug 168.

In some other embodiments, the S/D conductive plug 166 does not include a barrier layer. In some embodiments, the S/D conductive plug 166 includes a barrier layer, and the barrier layer is made of titanium (Ti), titanium nitride (TiN), tantalum (Ta), tantalum nitride (TaN), or another applicable material. In some other embodiments, the gate conductive plug 168 does not include a barrier layer. In some embodiments, the gate conductive plug 168 includes a barrier layer, and the barrier layer is made of titanium (Ti), titanium nitride (TiN), tantalum (Ta), tantalum nitride (TaN), or another applicable material.

In some embodiments, the S/D conductive plug 166 is made of conductive material, such as tungsten (W), ruthenium (Ru), molybdenum (Mo), titanium (Ti), copper (Cu), cobalt (Co), or the like. In some embodiments, the S/D conductive plug 166 is formed by performing a deposition process, such as chemical vapor deposition (CVD), physical vapor deposition (PVD), atomic layer deposition (ALD), or other applicable processes.

In some embodiments, the gate conductive plug 168 is made of conductive material, such as tungsten (W), ruthenium (Ru), molybdenum (Mo), titanium (Ti), copper (Cu), cobalt (Co), or the like. In some embodiments, the gate conductive plug 168 is formed by performing a deposition process, such as chemical vapor deposition (CVD), physical vapor deposition (PVD), atomic layer deposition (ALD), or other applicable processes.

Afterwards, as shown in FIG. 2D, a dielectric layer 170 is formed on the S/D conductive plug 166, the gate conductive plug 168 and the dielectric layer 164, in accordance with some embodiments.

The dielectric layer 170 may include multilayers made of multiple dielectric materials. In some embodiments, the dielectric layer 170 is made of LaO, AlO, YO, TaCN, ZrSi, SiOCN, SiOC, SiCN, LaO, ZrN, ZrAlO, TiO, TaO, ZrO, HfO, SiN, HfSi, AlON, SiO, SiC, ZnO and/or other applicable dielectric materials. In some embodiments, the dielectric layer 170 may be formed by chemical vapor deposition (CVD), physical vapor deposition (PVD), atomic layer deposition (ALD), or other applicable processes. In some embodiments, the dielectric layer 170 has a thickness in a range from about 2 nm to about 20 nm.

Next, as shown in FIG. 2E, a mask layer 171 is formed on the dielectric layer 170 and then patterned to form a patterned mask layer 171, in accordance with some embodiments.

Afterwards, as shown in FIG. 2F, the dielectric layer 170 is patterned by using the patterned mask layer 171 as a mask to form a trench 173, in accordance with some embodiments. The top surface of the conductive plug 166 and the top surface of the gate conductive plug 168 are exposed by the trench 173.

Next, as shown in FIG. 2G, a protection layer 174 is formed on the S/D conductive plug 166, the gate conductive plug 168, in accordance with some embodiments. The top surface of the protection layer 174 is higher than the bottom surface of the dielectric layer 170. The top surface of the protection layer 174 is higher than the top surface of the dielectric layer 164. The protection layer 174 is used to protect the conductive area.

It should be noted that the protection layer 174 is selectively formed on the conductive material, not formed on the dielectric material, and therefore the protection layer 174 is formed on the S/D conductive plug 166, the gate conductive plug 168, not formed on the dielectric layer 170. In other words, the protection layer 174 is selectively formed on the S/D conductive plug 166 and the gate conductive plug 168, without forming on the dielectric layer 170.

In some embodiments, the protection layer 174 is made of compound containing nitrogen (N) and aromatic rings. In some embodiments, the protection layer 174 is made of pyridine, aniline, pyrrole, or another applicable material.

In some embodiments, the protection layer 174 is formed by a deposition process under a pressure in a range from about 1 Torr to about 10 Torr. In some embodiments, the protection layer 174 is formed by a deposition process under a temperature in a range from about 150 Celsius degrees to about 250 Celsius degrees.

Afterwards, as shown in FIG. 2H, a passivation barrier layer 176 is formed on the dielectric layer 164 and the dielectric layer 170, in accordance with some embodiments. The passivation barrier layer 176 is used to protect the dielectric material and increase the selectivity between the conductive material and dielectric material.

It should be noted that passivation barrier layer 176 is selectively formed on the dielectric materials, and therefore the passivation barrier layer 176 is selectively formed on the dielectric layer 164 and the dielectric layer 170, not formed on the protection layer 174.

In some embodiments, the passivation barrier layer 176 is made of self-assembled monolayer (SAMs). In some embodiments, the passivation barrier layer 176 is made of aminosilane. In some embodiments, the passivation barrier layer 176 is made of dimethylamino-trimethylsilane (DMA-TMS or TMSDMA), hexamethyldisilazane (HMDS) or another applicable material. In some embodiments, the passivation barrier layer 176 is formed by a deposition process under a pressure in a range from about 1 Torr to about 10 Torr. In some embodiments, the passivation barrier layer 176 is formed by a deposition process under a temperature in a range from about 150 Celsius degrees to about 250 Celsius degrees.

Next, as shown in FIG. 2I, the protection layer 174 is removed to form a recess 175, in accordance with some embodiments. As a result, the protection layer 174 is exposed.

In some embodiments, the protection layer 174 is removed by an anneal process. In some embodiments, the anneal process is operated at a temperature in a range from about 350 Celsius degrees to about 450 Celsius degrees. In some embodiments, the anneal process is operated under hydrogen (H₂) gas.

Afterwards, as shown in FIG. 2J, a protruding conductive structures 180 are formed in the recess 175 and extends upwardly, in accordance with some embodiments. The protruding conductive structure 180 extends above the bottom surface of the dielectric layer 170.

It should be noted that the protruding conductive structure 180 is selectively formed on the conductive material, and therefore the protruding conductive structure 180 is formed on the S/D conductive plug 166, the gate conductive plug 168. The selectively is created by forming the protection layer 174 and the passivation barrier layer 176 in different areas. Therefore, the protruding conductive structure 180 can be formed on the exposed top surface of S/D conductive plug 166 and the gate conductive plug 168, rather than on the passivation barrier layer 176.

The protruding conductive structure 180 protrudes above the bottom surface of the dielectric layer 170. The topmost surface of the protruding conductive structure 180 is higher than the bottom surface of the dielectric layer 170. The protruding conductive structure 180 has a third height H3. In some embodiments, the third height H3 of the protruding conductive structure 180 is about 1 nm to about 5 nm. If the third height H3 of the protruding conductive structure 180 is less than 1 nm, the contact resistance is too small. If the third height H3 of the protruding conductive structure 180 is greater than 5 nm, the height uniformity of the protruding conductive structure 180 is hard to control.

In some embodiments, the top surface of the protruding conductive structure 180 is curved. In some embodiments, the protruding conductive structure 180 has polygon shape. The protruding conductive structure 180 is made of tungsten (W), Ruthenium (Ru), Molybdenum (Mo), titanium (Ti), or anther applicable material. The protruding conductive structure 180 is formed using chemical vapor deposition (CVD), atomic layer deposition (ALD), electroplating, another applicable method, or a combination thereof.

Next, as shown in FIG. 2K, the passivation barrier layer 176 is removed to expose the dielectric layer 164, in accordance with some embodiments.

In some embodiments, the passivation barrier layer 176 is removed by a plasma process. In some embodiments, the plasma is operated under nitrogen (N2), hydrogen H2 or another applicable gas.

Afterwards, as shown in FIG. 2L, a top portion of the protruding conductive structure 180 becomes a nitrided conductive layer 181, and a top portion of the dielectric layer 170 becomes a nitrided dielectric layer 182, a top portion of the dielectric layer 164 becomes a nitrided dielectric layer 183, in accordance with some embodiments. The nitrided conductive layer 181 is formed on the protruding conductive structure 180, and the nitrided dielectric layer 182 is formed on the dielectric layer 170. The nitrided dielectric layer 183 is formed on the dielectric layer 164.

The nitrided conductive layer 181, the nitrided dielectric layer 182 and the nitrided dielectric layer 183 are formed by performing a nitridation process 15 or a nitrogen implantation process 15. The nitrided conductive layer 181, the nitrided dielectric layer 182 and the nitrided dielectric layer 183 are used to as a block layer to prevent electromigration from overlying conductive layer 190 (formed later) to the S/D conductive plug 166 or the gate conductive plug 168.

In some embodiments, the nitrided conductive layer 181 is made of WₓN_{y}, RuₓN_{y}, CoₓN_{y}, MoₓN_{y}, TiN or the like. In some embodiments, the nitrided dielectric layer 182 and the nitrided dielectric layer 183 are made of SiN, SiOCN, SiCN, AlON, SiON or the like. In some embodiments, the nitrided conductive layer 181 has a thickness in a range from about 0.5 nm to about 5 nm. In some embodiments, the nitrided dielectric layer 182 has a thickness in a range from about 0.5 nm to about 5 nm. In some embodiments, the nitrided dielectric layer 183 has a thickness in a range from about 0.5 nm to about 5 nm.

In some embodiments, the nitridation process 15 is performed on the protruding conductive structure 180 and the dielectric layer 170. In some embodiments, the nitridation process 15 is performed by using precursor gas including ammonia (NH₃), a gas mixture of ammonia and hydrogen (NH₃/H₂), a gas mixture of nitrogen and hydrogen (N₂/H₂), another applicable gas or combination thereof. In some embodiments, the nitridation process 15 is performed at a pressure in a range from about 0.05 Torr to about 10 Torr. If the pressure is less than 0.05 Torr, the nitrided conductive layer 181 may not prevent the electromigration from overlying conductive layer 190 (formed later). If the pressure is greater than 10 Torr, the contact resistance between the nitrided conductive layer 181 and overlying layers may be too high.

In some embodiments, the nitridation process 15 is performed at a radiofrequency (RF) power in a range from about 30 W to about 1000 W. If the RF power is less than 30 W, the nitrided conductive layer 181 may not prevent the electromigration from overlying conductive layer 190 (formed later). If the RF power is greater than 1000 W, the contact resistance between the nitrided conductive layer 181 and overlying layers may be too high.

In some embodiments, the nitridation process 15 is performed at gas flow rate in a range from about 5 sccm to about 1000 sccm. If the gas flow rate is less than 5 sccm, the nitrided conductive layer 181 may not prevent the electromigration from overlying conductive layer 190 (formed later). If the gas flow rate is greater than the 1000 sccm, the contact resistance between the nitrided conductive layer 181 and overlying layers may be too high.

In some embodiments, the nitrogen implantation process 15 is performed by using nitrogen (N₂). In some embodiments, the nitrogen implantation process is performed at ion beam energy in a range from about 0.5 keV to about 1 keV. If the ion beam energy is less than 0.5 keV, the nitrided conductive layer 181 may not prevent the electromigration from overlying conductive layer 190 (formed later). If the ion beam energy is greater than 1 keV, the contact resistance between the nitrided conductive layer 181 and overlying layers may be too high.

In some embodiments, the ion implantation dose used in the nitrogen implantation process is at about 1E15 atom/cm² to about 1E17 atom/cm². If the ion implantation dose is less than 1E15 atom/cm^{2,} the nitrided conductive layer 181 may not prevent the electromigration from overlying conductive layer 190 (formed later). If the ion implantation dose is greater than 1E17 atom/cm², the contact resistance between the nitrided conductive layer 181 and overlying layers may be too high. In some embodiments, the title angle of the nitrogen ion implantation process 15 is about 0 degrees.

Next, as shown in FIG. 2M, a first barrier layer 184 is formed on the nitrided conductive layer 181, the nitrided dielectric layer 182 and the nitrided dielectric layer 183, in accordance with some embodiments.

In some embodiments, the first barrier layer 184 is made of TiN, TaN, or another applicable material. In some embodiments, the first barrier layer 184 has a thickness in a range from about 0.5 nm to about 10 nm. In some embodiments, the first barrier layer 184 is formed by chemical vapor deposition (CVD), atomic vapor deposition (ALD), physical vapor deposition (PVD), another suitable method, or a combination thereof.

Afterwards, as shown in FIG. 2N, a second barrier layer 186 is formed on the first barrier layer 184, in accordance with some embodiments. The first barrier layer 184 and the second barrier layer 186 are made of different materials.

In some embodiments, the second barrier layer 186 is made of cobalt (Co), Ruthenium (Ru), tungstic (W), molybdenum (Mo), or another applicable material. In some embodiments, the second barrier layer 186 has a thickness in a range from about 0.5 nm to about 10 nm. In some embodiments, the second barrier layer 186 is formed by chemical vapor deposition (CVD), atomic vapor deposition (ALD), physical vapor deposition (PVD), another suitable method, or a combination thereof.

Next, as shown in FIG. 2O, a seed layer 188 is formed on the second barrier layer 186, in accordance with some embodiments. The seed layer 188 is used to facilitate the formation of the conductive layer 190 (formed later).

In some embodiments, the seed layer 188 is made of cobalt (Co), Ruthenium (Ru), tungstic (W), molybdenum (Mo), or another applicable material. In some embodiments, the seed layer 188 has a thickness in a range from about 0.5 nm to about 10 nm. In some embodiments, the seed layer 188 is formed by chemical vapor deposition (CVD), atomic vapor deposition (ALD), physical vapor deposition (PVD), another suitable method, or a combination thereof.

Afterwards, as shown in FIG. 2P, a conductive layer 190 is formed on the seed layer 188, in accordance with some embodiments.

In some embodiments, the conductive layer 190 is made of Co, Cu or another applicable material. In some embodiments, the conductive layer 190 is formed by chemical vapor deposition (CVD), atomic vapor deposition (ALD), physical vapor deposition (PVD), another suitable method, or a combination thereof.

Next, as shown in FIG. 2Q, a portion of the conductive layer 190 is removed by using a planarization process, in accordance with some embodiments. The conductive layer 190 is electrically connected to the S/D conductive plug 166 and the gate conductive plug 188 by the protruding conductive structure 180.

In some embodiments, the conductive layer 190 is planarized by a chemical mechanical polishing (CMP) process. After the planarization process, in some embodiments, the conductive layer 190 has a thickness in a range from about 2 nm to about 20 nm.

The protection layer 174 is firstly formed on the conductive material, not on the dielectric material. Next, the passivation barrier layer 176 is formed on dielectric material, not on protection layer 174. Afterwards, after the protection layer 174 is removed to expose the top surfaces of the S/D conductive plug 166 and the gate conductive plug 168, the protruding conductive structures 180 are selectively formed on the top surfaces of the S/D conductive plug 166 and the gate conductive plug 168, not on the passivation barrier layer 176. By using the chemical properties of the protection layer 174 and the passivation barrier layer 176, the protruding conductive structures 180 can be selectively formed on the conductive materials.

Since the protruding conductive structure 180 extends upwardly above the bottom surface of the dielectric layer 170, the contact area of the protruding conductive structure 180 and the overlying layers are increased, therefore the contact resistance between the protruding conductive structure 180 and the first barrier layer 184, or the contact resistance between the nitrided conductive layer 181 and the first barrier layer 184, are decreased. Therefore, the performance of the semiconductor structure 100a is improved.

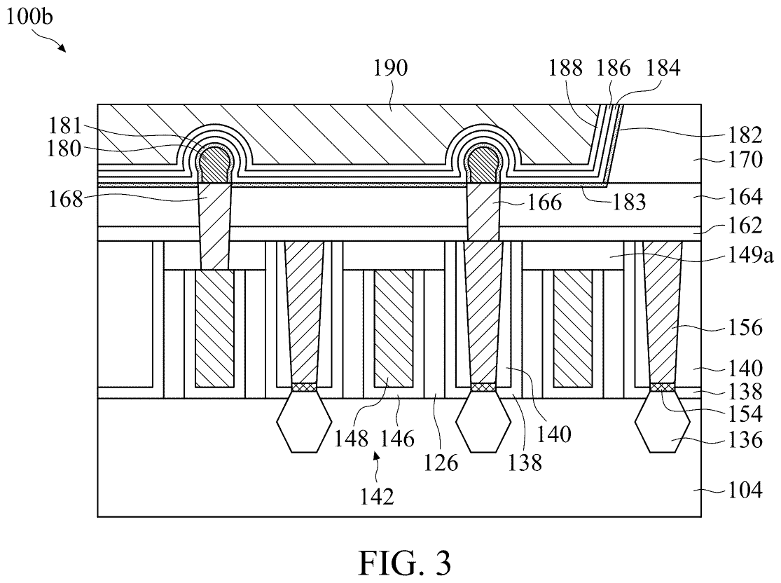

FIG. 3 illustrates a cross-sectional view of a semiconductor structure 100b, in accordance with some embodiments. The semiconductor structure 100b of FIG. 3 includes elements that are similar to, or the same as, elements of the semiconductor structure 100a of FIG. 2Q, the difference between FIG. 3 and FIG. 2Q is that top portion 149a of the gate mask layer is formed on the gate electrode layer 148, no bottom portion of the gate mask layer. The top portion 149a of the gate mask layer has a rectangular shape.

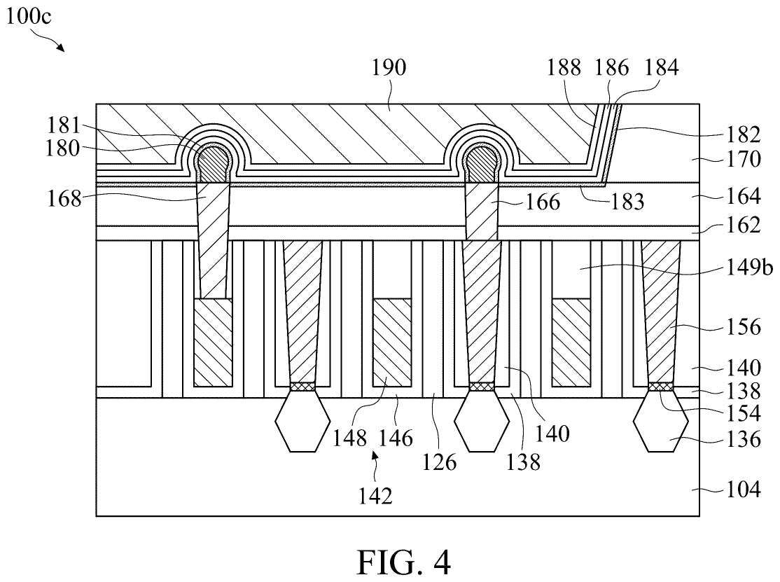

FIG. 4 illustrates a cross-sectional view of a semiconductor structure 100c, in accordance with some embodiments. The semiconductor structure 100c of FIG. 4 includes elements that are similar to, or the same as, elements of the semiconductor structure 100a of FIG. 2Q, the difference between FIG. 4 and FIG. 2Q is that no top portion of the gate mask layer. The top surface of the bottom portion 149b of the gate mask layer is substantially coplanar with the top surface of the gate dielectric layer 146 and the top surface of the gate spacer layer 126.

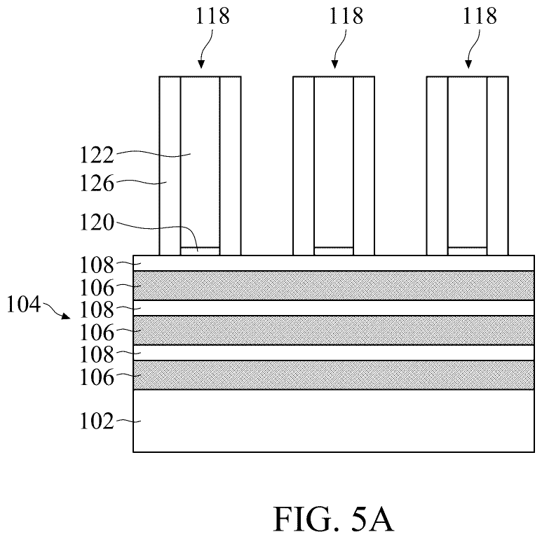

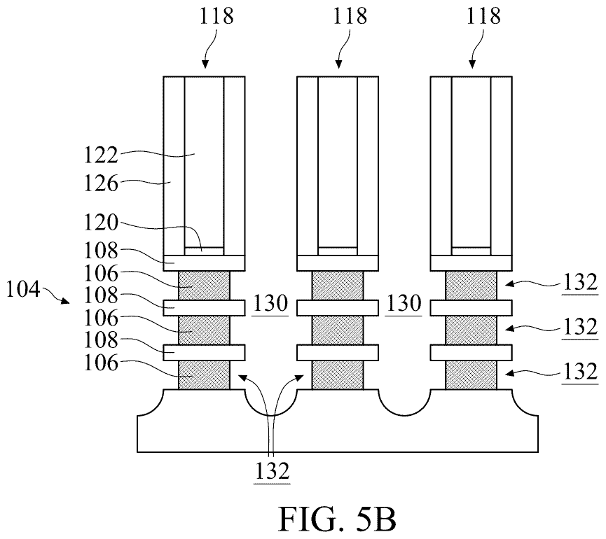

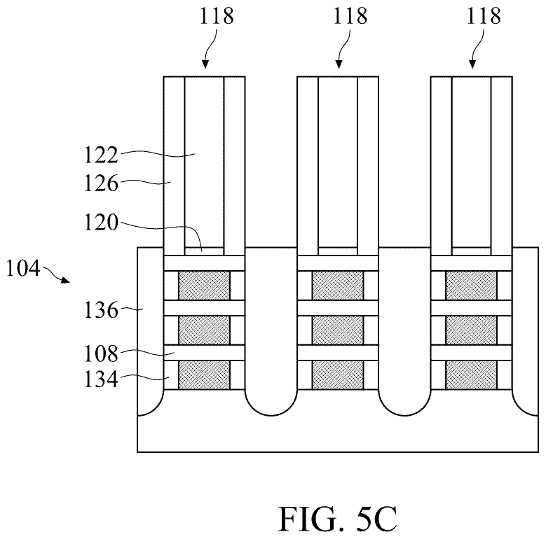

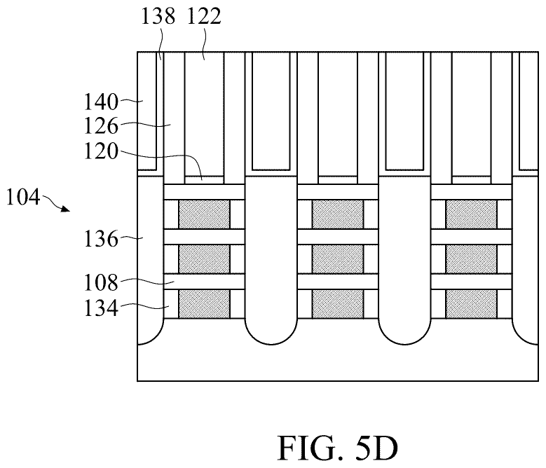

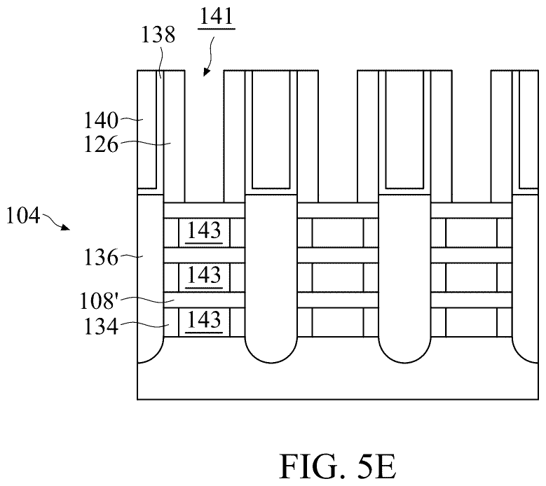

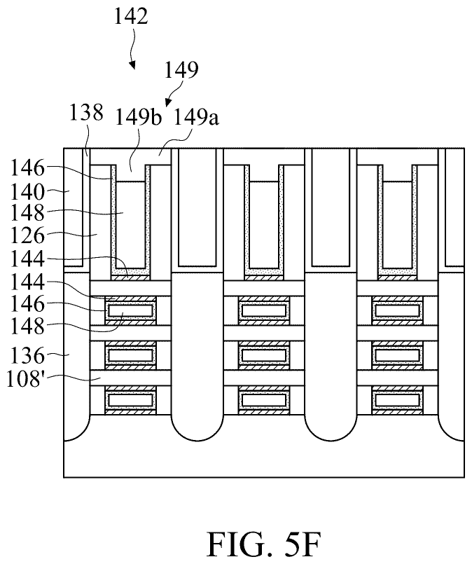

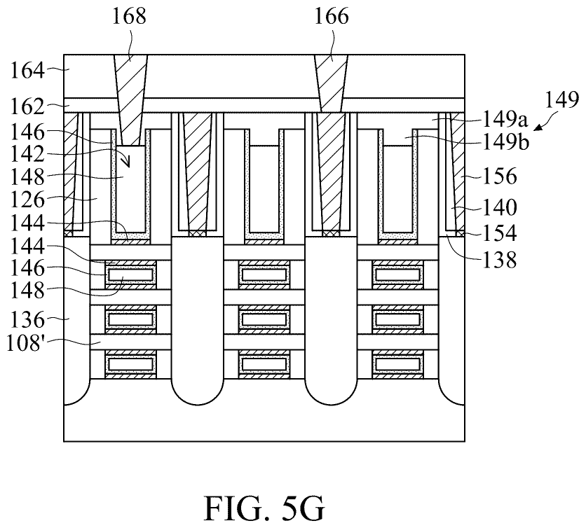

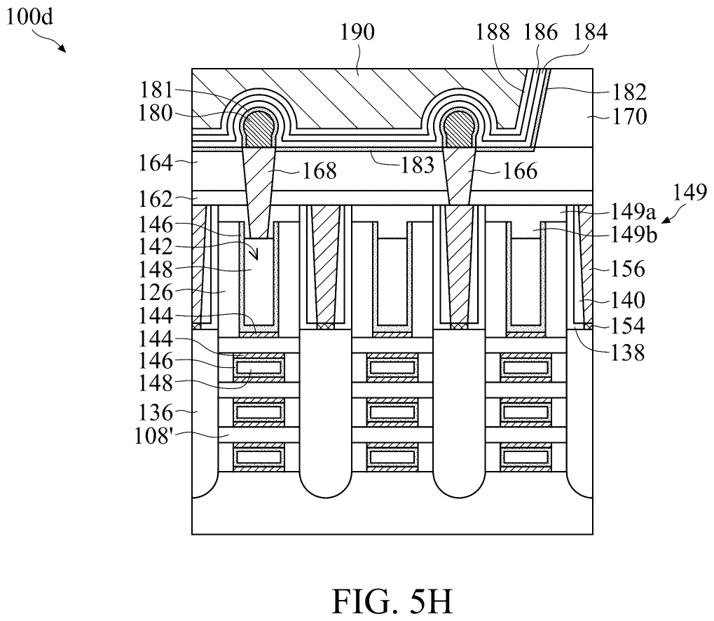

FIGS. 5A to 5H illustrate cross-sectional representations of various stages of manufacturing a semiconductor structure 100d, in accordance with some embodiments. The semiconductor structure 100d of FIGS. 5A to 5H includes elements that are similar to, or the same as, elements of the semiconductor structure 100a of FIG. 2A-2Q. The process for forming the semiconductor structure 100d are the same as, or similar to, the process for forming the semiconductor structure 100a.

As shown in FIG. 5A, the fin structure 104 includes first semiconductor material layers 106 and second semiconductor material layers 108 alternatively stacked.

In some embodiments, the first semiconductor material layers 106 and the second semiconductor material layers 108 are alternately stacked over the substrate 102. In some embodiments, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

The dummy gate structures 118 are formed across the fin structure 104 and extend over the isolation structure 114, in accordance with some embodiments. The dummy gate structures 118 may be used to define the source/drain regions and the channel regions of the resulting semiconductor structure 100d.

In some embodiments, the dummy gate structures 118 include dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

After the dummy gate structures 118 are formed, the gate spacer layers 126 are formed along and covering opposite sidewalls of the dummy gate structure 118. The gate spacers 126 may be configured to separate source/drain structures from the dummy gate structure 118 and support the dummy gate structure 118.

Next, as shown in FIG. 5B, a portion of the fin structure 104 is removed to form source/drain (S/D) recesses 130, and then the first semiconductor material layers 106 exposed by the source/drain recesses are laterally recessed to form notches 132, in accordance with some embodiments.

In some embodiments, an etching process is performed on the semiconductor structure 100d to laterally recess the first semiconductor material layers 106 of the fin structure 104 from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIG. 5C, inner spacer layers 134 are formed in the notches 132 between the second semiconductor material layers 108, in accordance with some embodiments. The inner spacer layers 134 are between the gate structure 142 and the S/D structure 136. The inner spacer layers 134 are configured to separate the source/drain (S/D) structures and the gate structures formed in subsequent manufacturing processes in accordance with some embodiments.

In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers 134 are formed by a deposition process, such as chemical vapor deposition (CVD) process, atomic layer deposition (ALD) process, another applicable process, or a combination thereof.

Next, after the inner spacers 134 are formed, the source/drain (S/D) structure 136 are formed in the S/D recesses 130, in accordance with some embodiments. In some embodiments, the source/drain (S/D) structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the source/drain (S/D) structures 136 are made of any applicable material, such as Ge, Si, GaAs, AlGaAs, SiGe, GaAsP, SiP, SiC, SiCP, or a combination thereof.

In some embodiments, the first source/drain (S/D) structure 136a and the second S/D structure 136b are in-situ doped during the epitaxial growth process. For example, are doped in one or more implantation processes after the epitaxial growth process.

Next, as shown in FIG. 5D, after the source/drain (S/D) structures 136 are formed, the contact etch stop layer (CESL) 138 is conformally formed to cover the S/D structures 136 and the interlayer dielectric (ILD) layer 140 is formed over the contact etch stop layers 138, in accordance with some embodiments.

Next, as shown in FIG. 5E, the dummy gate structure 118 is removed to form the trench 141, in accordance with some embodiments. As a result, the fin structure 104 exposed by the trench 141.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching.

Next, the first semiconductor material layers 106 are removed to form nanostructures 108′ with the second semiconductor material layers 108, in accordance with some embodiments. As a result, gaps 143 are formed between the nanostructures 108′ (or channel layers). The S/D structures 136 are attached to the nanostructures 108′. The fin structure 104 includes the nanostructures 108′.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

Next, as shown in FIG. 5F, after the nanostructures 108′ are formed, the gate structures 142 are formed to surround the nanostructures 108′ and over the isolation structure 110, in accordance with some embodiments. More specifically, the dummy gate structures 118 and the first semiconductor material layers 106 are removed to form nanostructures 108′ with the second semiconductor material layers 108, in accordance with some embodiments. The S/D structure 136 is attached to the nanostructures 108′.

After the nanostructures 108′ are formed, the gate structure 142 are formed wrapped around the nanostructures 108′. The gate structure 142 wrap around the nanostructures 108′ to form gate-all-around transistor structures in accordance with some embodiments. In some embodiments, the gate structure 142 includes an interfacial layer 144, the gate dielectric layer 146, and the gate electrode layer 148.

In some embodiments, the interfacial layers 144 are oxide layers formed around the nanostructures 108′ and on the top of the base fin structure 105. In some embodiments, the interfacial layers 144 are formed by performing a thermal process.

Next, the gate mask layer 149 is formed on the gate electrode layer 148. In some embodiments, the gate mask layer 149 has a T-shaped structure. The gate mask layer 149 has the top portion 149a and the bottom portion 149b. In some other embodiments, the gate mask layer 149 has a rectangular shape.

Afterwards, as shown in FIG. 5G, the silicide layer 154 and the S/D contact structure 156 is formed on the S/D structure 136. The top surface of the gate mask layer 149 is substantially coplanar with the top surface of the S/D contact structure 156. The S/D contact structure 156 is electrically connected to the S/D structure 136 by the silicide 154. Next, the etch stop layer 162 is formed over the gate structure 142, and the dielectric layer 164 is formed over the etch stop layer 162.

Next, the S/D conductive plug 166 is formed over the S/D contact structure 156, and the gate conductive plug 168 is formed over the first gate structure 142a and the second gate structure 142b. The S/D conductive plug 166 is electrically connected to the S/D contact structure 156. The gate conductive plug 168 is electrically connected to the gate electrode layer 148 of the gate structure 142. In addition, the gate conductive plug 168 passes through the gate mask layer 149.

Next, as shown in FIG. 5H, a series of processes, similar to or the same as shown in FIGS. 2D-2Q, are performed on the semiconductor structure 100d, in accordance with some embodiments. As a result, the protruding conductive structure 180 is selectively formed on the S/D conductive plug 166 and the gate conductive plug 168.

Similar to FIGS. 2D-2F, the dielectric layer 170 is formed on the dialectic layer 164 and then patterned to form the patterned dielectric layer 170. Next, similar to FIG. 2G, the protection layer 174 is selectively formed on the S/D conductive plug 166 and the gate conductive plug 168. Afterwards, similar to FIG. 2H, the passivation barrier layer 176 is formed on the dielectric layer 164 and the dielectric layer 170, not on protection layer 174.

Next, similar to FIG. 2I, the protection layer 174 is removed to form the recess, and then similar to in FIG. 2J, the protruding conductive structures 180 are formed on the top surface of the S/D conductive plug 166 and the top surface of the gate conductive plug 168. Next, similar to FIG. 2K, the passivation barrier layer 176 is removed. Afterwards, similar to FIG. 2L, the nitrided conductive layer 181, the nitrided dielectric layer 182 and the nitrided dielectric layer 183 are formed by performing the nitridation process 15 or a nitrogen implantation process 15. Next, similar to FIGS. 2M-2P, the first barrier layer 184, the second barrier layer 186, the seed layer 188 and the conductive layer 190 are sequentially formed on the protruding conductive structures 180.

Since the protruding conductive structure 180 extends upwardly above the bottom surface of the dielectric layer 170, the contact area of the protruding conductive structure 180 and the overlying layers are increased, therefore the contact resistance between the protruding conductive structure 180 and the first barrier layer 184, or the contact resistance between the nitrided conductive layer 181 and the first barrier layer 184, are decreased. Therefore, the performance of the semiconductor structure 100a is improved.

The semiconductor structures 100a-100d includes the protruding conductive structure 180 selectively formed on the S/D conductive plug 166 and the gate conductive plug 168 by creation of the selectivity between the conductive material and the dielectric material. The protection layer 174 is firstly formed on the conductive material, not on the dielectric material. Next, the passivation barrier layer 176 is formed on dielectric material, not on protection layer 174. Afterwards, after the protection layer 174 is removed to expose the top surfaces of the S/D conductive plug 166 and the gate conductive plug 168, the protruding conductive structures 180 are selectively formed on the top surfaces of the S/D conductive plug 166 and the gate conductive plug 168, not on the passivation barrier layer 176. By using the chemical properties of the protection layer 174 and the passivation barrier layer 176, the protruding conductive structures 180 can be selectively formed on the conductive materials.

The protruding conductive structures 180 protrudes from the top surface of the dielectric layer 164 to provide more contact area. Therefore, the contact resistance between the protruding conductive structures 180 and the overlying layers is reduced to improve the performance of the semiconductor structures 100a-100d.

Furthermore, since the nitrided conductive layer 181, the nitrided dielectric layer 182 and the nitrided dielectric layer 183 are used to as a block layer to prevent electromigration from overlying conductive layer 190 to the S/D conductive plug 166 or the gate conductive plug 168.

It should be noted that same elements in FIGS. 1A to 5H may be designated by the same numerals and may include similar or the same materials and may be formed by similar or the same processes; therefore such redundant details are omitted in the interest of brevity. In addition, although FIGS. 1A to 5H are described in relation to the method, it will be appreciated that the structures disclosed in FIGS. 1A to 5H are not limited to the method but may stand alone as structures independent of the method. Similarly, although the methods shown in FIGS. 1A to 5H are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structures may include a fin structure over a substrate. A gate structure formed over the fin structure and an S/D structure adjacent to the gate structure. An S/D contact structure is formed on the S/D structure, and an S/D conductive plug is formed on the S/D contact structure. A gate conductive plug is formed on the gate structure. The protruding conductive structures are formed on the S/D conductive plug and the gate conductive plug. The protruding conductive structures extends upwardly above the bottom surface of the dielectric layer. The protruding conductive structures can be selectively formed on conductive materials. The contact area between the protruding conductive structures and overlying layers is increased, and therefore the contact resistance is decreased. Therefore, the performance of the semiconductor structure is improved.

In some embodiments, a method for forming a semiconductor structure is provided. The method includes forming a fin structure over a substrate, and forming an S/D structure over the fin structure. The method includes forming an S/D conductive plug over the S/D structure and in a dielectric layer, and forming a protection layer on the S/D conductive plug. The method includes forming a passivation barrier layer on the dielectric layer, and removing the protection layer to form a recess. The method also includes forming a protruding conductive structure in the recess, and the protruding conductive structure extends above the top surface of the dielectric layer. The method includes removing the passivation barrier layer to expose the dielectric layer, and forming a nitrided conductive layer on the protruding conductive structure. The method includes forming a conductive layer on the protruding conductive structure.

In some embodiments, a method for forming a semiconductor structure is provided. The method includes forming a fin structure over a substrate, and the fin structure comprises first semiconductor material layers and second semiconductor material layers alternately stacked structure over the substrate. The method includes forming a dummy gate structure over the fin structure, and forming an S/D structure adjacent to the dummy gate structure. The method includes removing the dummy gate structure, and removing the first semiconductor material layers to form a plurality of nanostructures. The method also includes forming a gate structure surrounding the nanostructures, and forming a dielectric layer over the gate structure. The method includes forming a gate conductive plug over the gate structure and in the dielectric layer, and forming a protection layer on the gate conductive plug. The method also includes forming a passivation barrier layer on the dielectric layer, and removing the protection layer to form a recess. The method includes forming a protruding conductive structure in the recess, and the protruding conductive structure extends above a top surface of the dielectric layer. The method includes removing the passivation barrier layer to expose the dielectric layer, and forming a nitrided conductive layer on the protruding conductive structure. The method includes forming a conductive layer on the protruding conductive structure.

In some embodiments, a semiconductor structure is provided. The semiconductor structure includes a gate structure formed over a substrate, and a source/drain (S/D) structure formed adjacent to the gate structure. The semiconductor structure includes an S/D conductive plug over the S/D structure and in a dielectric layer, and a protruding conductive structure on the S/D conductive plug. The protruding conductive structure extends above a top surface of the dielectric layer. The semiconductor structure includes a conductive layer formed on the protruding conductive structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a fin structure over a substrate;
forming an S/D structure over the fin structure;
forming an S/D conductive plug over the S/D structure and in a dielectric layer;
forming a protection layer on the S/D conductive plug;
forming a passivation barrier layer on the dielectric layer;
removing the protection layer to form a recess;
forming a protruding conductive structure in the recess, wherein the protruding conductive structure extends above a top surface of the dielectric layer;
removing the passivation barrier layer to expose the dielectric layer;
forming a nitrided conductive layer on the protruding conductive structure; and
forming a conductive layer on the protruding conductive structure.

2. The method for forming the semiconductor structure as claimed in claim 1, further comprising:
forming a first barrier layer on the nitrided conductive layer; and
forming a second barrier layer on the first barrier layer, wherein the first barrier layer and the second barrier layer are made of different materials.

3. The method for forming the semiconductor structure as claimed in claim 1, wherein removing the protection layer comprises performing an anneal process.

4. The method for forming the semiconductor structure as claimed in claim 1, wherein the protection layer is selectively formed on the S/D conductive plug without forming on the dielectric layer.

5. The method for forming the semiconductor structure as claimed in claim 1, wherein forming the nitrided conductive layer comprises performing a nitridation process.

6. The method for forming the semiconductor structure as claimed in claim 1, wherein forming the nitrided conductive layer comprises performing a nitrogen implantation process.

7. The method for forming the semiconductor structure as claimed in claim 1, further comprising:
forming an S/D contact structure over the S/D structure, wherein the S/D conductive plug is electrically connected to the S/D structure by the S/D contact structure.

8. The method for forming the semiconductor structure as claimed in claim 1, wherein the protection layer comprises compound containing nitrogen (N) and aromatic rings.

9. The method for forming the semiconductor structure as claimed in claim 1, wherein the passivation barrier layer comprises aminosilane.

10. A method for forming a semiconductor structure, comprising:
forming a fin structure over a substrate, wherein the fin structure comprises first semiconductor material layers and second semiconductor material layers alternately stacked structure over the substrate;
forming a dummy gate structure over the fin structure;
forming an S/D structure adjacent to the dummy gate structure;
removing the dummy gate structure;
removing the first semiconductor material layers to form a plurality of nanostructures;
forming a gate structure surrounding the nanostructures;
forming a dielectric layer over the gate structure;
forming a gate conductive plug over the gate structure and in the dielectric layer;
forming a protection layer on the gate conductive plug;
forming a passivation barrier layer on the dielectric layer;
removing the protection layer to form a recess;
forming a protruding conductive structure in the recess, wherein the protruding conductive structure extends above a top surface of the dielectric layer;
removing the passivation barrier layer to expose the dielectric layer;
forming a nitrided conductive layer on the protruding conductive structure; and
forming a conductive layer on the protruding conductive structure.

11. The method for forming the semiconductor structure as claimed in claim 10, further comprising:
removing a portion of the first semiconductor material layers to form notches; and
forming an inner spacer layer in the notches, wherein the inner spacer layer is between the gate structure and the S/D structure.

12. The method for forming the semiconductor structure as claimed in claim 10, further comprising:
forming a gate mask layer over the gate structure, wherein the gate conductive plug passes through the gate mask layer.

13. The method for forming the semiconductor structure as claimed in claim 12, further comprising:
forming a gate spacer layer on a sidewall surface of the gate structure, wherein the gate mask layer is formed on the gate spacer layer.

14. The method for forming the semiconductor structure as claimed in claim 10, further comprising:
performing a nitridation process on the dielectric layer to form a nitrided dielectric layer.

15. The method for forming the semiconductor structure as claimed in claim 10, further comprising:
performing a nitrogen implantation process on the dielectric layer to form a nitrided dielectric layer.

16. The method for forming the semiconductor structure as claimed in claim 10, further comprising:
forming a first barrier layer on the nitrided conductive layer; and
forming a second barrier layer on the first barrier layer, wherein the first barrier layer and the second barrier layer are made of different materials.

17. A semiconductor structure, comprising:
a gate structure formed over a substrate;
a source/drain (S/D) structure formed adjacent to the gate structure;
an S/D conductive plug formed over the S/D structure and in a dielectric layer;
a protruding conductive structure formed on the S/D conductive plug, wherein the protruding conductive structure extends above a top surface of the dielectric layer; and
a conductive layer formed on the protruding conductive structure.

18. The semiconductor structure as claimed in claim 17, further comprising:
a nitrided conductive layer formed on the protruding conductive structure.

19. The semiconductor structure as claimed in claim 17, further comprising:
a gate mask layer over the gate structure; and
a gate conductive plug over the gate structure, wherein the gate conductive plug passes through the gate mask layer.

20. The semiconductor structure as claimed in claim 17, further comprising:
a plurality of nanostructures formed over the substrate, wherein the nanostructures are wrapped by the gate structure.
